(19) United States
(12) Patent Application Publication
(10) Pub. No.: US 2010/0101621 A1
(43) Pub. Date: Apr. 29, 2010

(54) Solar powered generating apparatus and methods

(76) Inventor: Jun Xu, Carlsbad, CA (US)

Correspondence Address: Robert F. Gazdzinski, Esq.;GAZDZINSKI & ASSOCIATES, 11440 West Bernado Court, Suite 375, San Diego, CA, 92127, US

(21) Appl. No.: 12/290,222

(22) Filed: Oct. 28, 2008

(51) Int. Cl. H01L 35/00

(52) U.S. Cl. 136/206

(57) ABSTRACT

Methods and apparatus for generation of thermoelectric power. In one embodiment, thermoelectric power is generated via a solar power collector; a solar power receiver; and a power conversion unit. The solar power collector focuses energy from the sun onto the receiver. A phase change material adapted to store the radiant energy from the sun in the form of thermal energy is provided to the receiver. Stored energy is converted, at the power conversion unit, into electricity. A cold thermal storage device for storing cooled phase change material and a hot thermal storage device for storing heated phase change material may also be provided. Pumps utilizing energy produced by the system (or another source) may be provided to move the phase change material. The system may use stacked components to provide an integrated and compact thermoelectric power generation apparatus. Electricity is produced with zero-emissions, low cost, and dependable capacity.

### COPYRIGHT

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### BACKGROUND OF THE INVENTION

1. Field of the Invention

The present invention relates generally to power generation systems. In one exemplary aspect, the invention describes a distributed thermoelectric power generation system which produces electric power via utilization of solar-heated phase change material.

2. Description of Related Technology

Photovoltaics (PV) is the field of technology and research related to the application of solar cells for energy. Photovoltaic devices convert sunlight directly into electricity. Photovoltaics are known for their use in generating electric power by using solar cells packaged in photovoltaic modules, often electrically connected in multiples as solar arrays, to convert energy from the sun into electricity. The term “photovoltaic” denotes the unbiased operating mode of a photodiode in which current through the device is due to the incident light energy. However, one of the drawbacks of PV devices is that PV panels only generate electricity intermittently. Many factors contribute to this intermittent generation. Most notably, solar energy is not available at night, sunlight is scarce in the winter (especially in latitudes further away from the equator), and the performance of solar power systems is affected by unpredictable weather patterns (e.g., cloud cover which obscures or mitigates radiant solar energy).

The well-known thermoelectric effect is the direct conversion of temperature differences to electric voltage and vice versa. Thomas Johann Seebeck discovered (in 1821) that the needle of a compass was deflected when it was placed near a loop made of two different metals and one of the two junctions was heated. The deflection was proportional to the temperature difference and depended on the metals used. Jean Peltier proved (in 1834) the opposite effect: an electric current flowing through these junctions causes the absorption or liberation of heat depending on the direction of the current. Thus, a thermoelectric device creates a voltage when there is a different temperature on each side, and when a voltage is applied to it, it creates a temperature difference.

These discoveries led to the design of thermoelectric generators (thermopiles). A thermopile is an electronic device that converts thermal energy into electrical energy. It is composed of thermocouples either connected in series or in parallel. FIG. 1 is a graphical illustration of an exemplary thermocouple 100 according to the prior art. Thermopiles do not measure the absolute temperature, but generate output proportional to a local temperature difference or temperature gradient. Typically, a relatively large number of thermocouples 100 are connected in series or in parallel, alternatively heated and cooled to generate a meaningful voltage.

A number of commercially available thermoelectric generators are available today. While these products and their respective designs differ one from another, most of them do share some common characteristics. At the core every thermoelectric generator is a hermetically sealed thermopile, comprising one or more thermocouples 100, such as that illustrated in FIG. 1. A thermopile typically contains a very large array of semiconductor elements. A gas burner keeps a high temperature on the hot side 102 while cooling fins ensure the cool side 104 remains comparatively cool via e.g., air convection and radiation. As long as the temperature difference is maintained, this arrangement creates a significant temperature gradient across the thermopile, and thus generates a steady DC current.

A number of different approaches for thermoelectric power generation and improvements thereto have been described in the prior art. For example, U.S. Pat. No. 6,625,990 to Bell issued Sep. 30, 2003 and entitled “Thermoelectric Power Generation Systems” discloses an improved thermoelectric power generation system which utilizes rotary thermoelectric configurations to improve and increase thermal power throughput. These systems are further enhanced by the use of hetrostructure thermoelectric materials, very thin plated materials, and deposited thermoelectric materials, which operate at substantially higher power densities than typical of the previous bulk materials.

U.S. Pat. No. 6,598,405 to Bell issued Jul. 29, 2003 and entitled “Thermoelectric Power Generation Utilizing Convective Heat Flow” describes an improved efficiency thermoelectric power generation system wherein convection is actively facilitated through a thermoelectric array, and the thermoelectric array is used to generate electrical power. Thermal power is convected through the thermoelectric array or arrays toward at least one side of the thermoelectric array, which leads to increased efficiency. Thermal power is applied to the array, creating a temperature gradient across the array. The thermoelectric system may also be combined with other power generation systems, forming a co-generation system.

U.S. Pat. No. 6,539,725 to Bell issued Apr. 1, 2003 and entitled “Efficiency Thermoelectrics Utilizing Thermal Isolation” discloses an improved efficiency thermoelectric system and method of making such a thermoelectric system. Significant thermal isolation between thermoelectric elements in at least one direction across a thermoelectric system provides increased efficiency over conventional thermoelectric arrays. Significant thermal isolation is also provided for at least one heat exchanger coupled to the thermoelectric elements. In one embodiment, the properties, such as resistance or current flow, of the thermoelectric elements may also be varied in at least one direction across a thermoelectric array. In addition, the mechanical configuration of the thermoelectric elements may be varied, in one embodiment, according to dynamic adjustment criteria.

U.S. Pat. No. 6,637,210 to Bell issued Oct. 28, 2003 and entitled “Thermoelectric Transient Cooling and Heating Systems” describes an improved efficiency thermoelectric system which operates the thermoelectric elements in the system in a non-steady state manner. The thermoelectric elements are powered for predefined periods of time to obtain increased efficiency. This benefit can be improved by also altering the resistance of the thermoelectric elements during the power-on period such that resistive heating is minimized.

U.S. Pat. No. 6,606,866 to Bell issued Aug. 19, 2003 and entitled “Thermoelectric Heat Exchanger” discloses a system for thermally conditioning and pumping a fluid. The system includes a thermoelectric heat exchanger having a thermoelectric device configured to pump heat. Heat exchangers are provided for transferring heat to and from the thermoelectric device and for generating a fluid flow across the thermoelectric device. The conditioned fluid may be placed in thermal communication with a variety of objects, such as a vehicle seat, or anywhere localized heating and cooling are desired. Thermal isolation may also be provided in the direction of flow to enhance efficiency.

Despite the foregoing approaches, certain problems still exist in the art of thermoelectric power generation. In particular, natural gas or other fossil fuels are often required to produce the temperature difference needed by thermoelectric power generators. For example, Global Thermoelectric, Inc. of Calgary, Alberta, Canada provides retail thermoelectric generators such as the GlobatHybrid model 5060 which combines a photovoltaic system with a fuel-based generator.

Fossil fuels (coal, oil and natural gas), are a non-renewable source of energy. Formed from plants and animals that lived up to 300 million years ago, fossil fuels are found in deposits beneath the earth. The fuels are burned to release the chemical energy that is stored within this resource. Among others, fossil fuels present the following problems:(i) when burned for fuel, deleterious or even toxic gases and other emissions like sulfur dioxide, nitrogen oxide, carbon dioxide, carbon monoxide, and particulates are released into the atmosphere, polluting the air and potentially exacerbating effects such as global warming, depletion of the ozone layer, and “acid raid”;(ii) oil drilling and transport of oil in the ocean as well as mining, drilling, and transportation on land increases the risk of oil spills and other damaging environmental effects; and (iii) the supply of fossil fuels is being depleted; and the cost-effective supply may eventually be completely consumed (which may have geo-political and economic consequences for the country or world as a whole).

Renewable energy resources, on the other hand, offer many advantages over fossil fuels. Renewable energy resources include without limitation the sun, wind, water (including tidal and wave energy), and biomass (plants and other organic material). The main benefits of renewable energy resources include (i) they are effectively inexhaustible resources; (ii) most of them do not produce significant amounts of pollution (or are much less polluting than fossil fuel counterparts); and (iii) potential economic benefits such as reduced cost and maintenance.

Thermoelectric power generation systems utilizing renewal resources are disclosed in the prior art. However, such systems continue suffer many other problems relating to storage and system reliability (as will be discussed below).

For example, U.S. Pat. No. 7,273,981 to Bell issued Sep. 25, 2007 and entitled “Thermoelectric Power Generation Systems” discloses representative configurations for improved thermoelectric power generation systems to improve and increase thermal efficiency. In one embodiment, a thermoelectric power generation system is disclosed comprising: a plurality of thermoelectric elements forming a rotary assembly with hot and cold heat exchangers. The rotation of the assembly causes the heat exchangers to pump hot and cold fluids respectively. A working media collects waste heat from the cold heat exchanger, and after collecting the waste heat, the working media is further heated and then dispenses at least a portion of its heat to the hot heat exchanger, thereby generating power with at least some of the plurality of thermoelectric elements. However no means are given for the storage of heat energy so that the system may be relied upon during instances of no sunlight. The invention further does not give mechanisms for ensuring efficiency, such as by providing focusing of the received sunlight.

U.S. Pat. No. 6,717,043 to Hasegawa, et al. issued Apr. 6, 2004 and entitled “Thermoelectric Power Generator” discloses a thermoelectric power generator which is capable of generating electric power from solar heat, geothermal heat or exhaust heat of low or medium temperature. The thermoelectric power generator operates via a working mechanism where a slightly hydrated sulfide semiconductor layer, having one side in contact with a low Fermi level redox reaction and having the other side in contact with a high Fermi level reaction generated by reactive metal cathode, allows electron transfer from the redox reaction into the cathode. This is accomplished by a thermal excitation step between both energy bands followed by a charge separation step driven by the internal electric field. The difference between the Fermi levels of the energy bands results in a useful electromotive ability.

U.S. Pat. No. 6,957,536 to Litwin, et al. issued Oct. 25, 2005 and entitled “Systems and Methods for Generating Electrical Power from Solar Energy” discloses systems and methods capable of producing electrical power from solar energy through the use of air cycles without fossil fuel combustion. The system includes a solar receiver, a generator, a compressor, and an expander. The expander is coupled to the generator to drive the generator and coupled to the compressor to drive the compressor. The system uses solar generated heat from the solar receiver to heat compressed air from the compressor. The solar generated heat can be directly transferred from the solar receiver to the compressed air as the compressed air flows through receiver tubes of the solar receiver, or the solar receiver can transfer the solar generated heat to a liquid metal, with the liquid metal transferring thermal energy to the compressed air. The expander receives and expands the heated compressed air to drive the generator to produce electricity, and to drive the compressor to compress air.

U.S. Pat. No. 6,668,555 to Moriarty issued Dec. 30, 2003 and entitled “Solar Receiver-Based Power Generation System” discloses a solar receiver system which has a solar receiver that receives sun rays directed thereto. The receiver has a heat pipe having working fluid therein. The first end of heat pipe and a second end form a respective first condenser and a second condenser. An evaporator portion is disposed between the ends. The first end has an air manifold therearound. The second end has a liquid manifold therearound. The heated air from the air manifold is provided to a power generation device. The power generation device receives heated air from the air manifold which is expanded in a turbine to extract mechanical work therefrom. The turbine may be coupled to a generator for generating electrical power in response to the mechanical energy.

### Energy Storage—

Storage is an important issue in the development of solar energy systems because modern energy systems usually assume continuous availability of energy. As previously noted, solar energy is not available at night, sunlight is scarce in the winter, and the performance of solar power systems is affected by unpredictable weather patterns; therefore, storage media and/or back-up power systems become very important considerations.

Various types of power generation systems adapted to store accumulated heat are disclosed in the prior art. For example, U.S. Pat. No. 7,191,597 to Goldman issued Mar. 20, 2007 and entitled “Hybrid Generation with Alternative Fuel Sources” discloses a generating facility for generating electricity from both solar and non-solar energy sources. The solar generating portion of the facility includes capability to directly generate electricity from solar insolation, or to store the solar energy in a tangible medium, including stored heat, or solar generating fuel. The generating facility is configured to generate electricity simultaneously from both solar and non-solar sources, as well as solely from immediate solar insolation and from solar energy stored in a tangible medium. Additionally, the solar generating capacity may be segregated; such that separate spectra of solar insolation are used to capture heat for steam turbine based electrical generation, capture light energy for photovoltaic based electrical generation, and to grow biomass to generate a solar fuel.

U.S. Pat. No. 7,171,812 to Schubert issued Feb. 6, 2007 and entitled “Electric Generation Facility and Method Employing Solar Technology” discloses an electric generation station which employs a solar array to heat a thermal transfer fluid that is supplied to a heat exchanger to produce steam. The heated steam drives a steam engine that operates either an electric generator to produce electricity or a pump assembly. The pump assembly can pump water to an elevated location for use during peak times by flowing water downwardly past an electric generator. The electric generators can be pelton turbines. One or more thermal fluid storage facilities can be used to store heated fluid, and heat may also be stored in a heat retaining material. Additional optional features and combinations of optional assemblies are disclosed. A method of generating electricity with these systems is also described.

U.S. Pat. No. 6,314,978 to Lanning, et al. issued Nov. 13, 2001 and entitled “Reciprocating Feed System for Fluids” discloses pressurized storage tanks. To produce a high pressure stream of fluid, such as propellant, the fluid is transferred from a low pressure reservoir into a plurality of intermediate storage tanks, in which the fluid is pressurized. The fluid is drained from the storage tanks to an outlet in sequence. While one pressurized storage tank in a three pressurized tank system is being drained, the most recently drained one of the storage tanks is being vented, and still another of the storage tanks is being filled or replenished with fluid, as the case may be, from the low pressure reservoir.

Phase change material (PCM) may also be utilized in thermal power generation. PCMs are substances with a high heat of fusion which, upon melting and subsequent solidifying at a certain temperature, is capable of storing and releasing large amounts of energy. Heat is absorbed or released when the material changes from solid to liquid and vice versa. Initially, solid-liquid PCMs operate in a similar fashion to conventional storage materials; their temperature increases as they absorb heat. However, when PCMs reach their melting point, they absorb large amounts of heat without a significant increase in temperature (“latent heat”). When the ambient temperature around a liquid material drops, the PCM solidifies, releasing its stored latent heat.

So-called “molten salt” is a colloquial name given to a useful category of materials and processes. It is one of the most commonly used PCMs. Molten salt typically comprises a mixture of sodium-nitrate and potassium-nitrate (commonly called “saltpeter”), in a prescribed ration (e.g., 60%/40%, respectively). The salt melts at about 430 F. In the liquid state, molten salt has a viscosity and appearance similar to water. Molten salt is a heat storage medium that retains thermal energy very effectively over time, and is capable of operating at temperatures greater than 1000 F. In addition, molten salt is a non-toxic, low-cost, and readily available material.

Thermal energy storage technologies store heat, usually from active solar collectors, in an insulated repository for later use. One of the applications of thermal energy storage is to generate electricity. Molten salt has been proposed as a means to retain a high temperature thermal store for later use in electricity generation. Thermal energy storage is widely regarded as one of the most promising technologies by the renewable energy campaign because, unlike many intermittent renewable resources, it offers a zero-emission technology with dependable capacity. The thermal energy storage system provides an additional benefit: it allows any associated power plant to be designed to optimize the electricity load profile to meet specific market needs.

A number of high-profile thermal energy storage projects are currently underway. While the design philosophy, capacity, and operation details of these projects vary considerably from one project to another, they do share some common characteristics. Below is a description of this technology.

In a typical thermal storage technology, a solar power tower design is employed. This design allows power generation by focusing sunlight onto a tower-mounted central heat exchanger or receiver. A large number of sun tracking mirrors are used to reflect and concentrate the solar radiation onto the receiver. Molten salt is circulated through tubes in the receiver, collecting the energy gathered from the sun. The heated molten salt is then directed to an insulated hot thermal storage tank, where the energy can be stored with minimal energy losses. When electricity is to be produced, the molten salt stored in the hot thermal storage tank is directed to a heat exchanger (or steam generator) and used to produce steam at high temperature and pressure. The steam is then used to power a conventional steam turbine which is coupled to an electrical generator, the latter producing electricity. After exiting the steam generator, the molten salt is sent to the cold thermal storage tank and the cycle repeats itself.

One example of a prior art system utilizing molten salt is given in European Patent Application No. EP 1873397 to Litwin, et al. published Jan. 2, 2008 and entitled “High Temperature Molten Salt Solar Receiver” which discloses a high temperature solar power tower system that includes a molten salt heat transfer medium, a high temperature solar receiver, and an energy conversion system. The molten salt heat transfer medium is capable of being heated to a temperature of at least approximately 1200 degrees Fahrenheit (649° C.) by the high temperature solar receiver. The energy conversion system uses the heated molten salt to generate power.

Also, U.S. Pat. No. 6,931,851 to Litwin issued Aug. 23, 2005 and entitled “Solar Central Receiver with Inboard Headers” discloses a solar power plant having a plurality of receiver panels mounted in a circular fashion about a solar receiver. Each receiver panel includes a plurality of tubes that terminate at each end at a header. To eliminate the presence of gaps between the tubes of adjacent receiver panels the headers are staggered or beveled. In the staggered configuration the headers of adjacent receiver panels are located in different elevations so that the headers of adjacent receiver panels may overlap each other, thus allowing the headers and tubes of adjacent receiver panels to be positioned closer together to eliminate gaps between the tubes of adjacent panels. In the beveled configuration the headers are angled such that the terminal ends of adjacent headers are parallel and positioned in a closely abutting relationship, resulting in the absence of gaps between adjacent headers and tubes.

U.S. Pat. No. 4,438,630 to Rowe issued Mar. 27, 1984 and entitled “Method and System for Maintaining Operating Temperatures in a Molten Salt Co-Generating Unit” discloses a method of operating a co-generating steam supply system having two units, the second of which utilizes a molten-salt primary heat transfer fluid, is disclosed for utilizing the steam produced by the first unit for maintaining selected component operating temperatures in the second unit during periods when the second unit is not producing steam. The steam generator of the second unit is maintained at operating temperature by reversing the fluid flow through both the shell and tube sides. The reverse flow of molten salt is in heat exchange relation with the reverse flow of steam drawn from the steam flow line of the first unit.

It should be noted that while large scale solar thermal power plants (with or without thermal storage) are attractive in many ways, they face significant challenges. First, large solar thermal plants need transmission lines to carry electricity to population centers. Since solar power plants are often located in remote areas, like ridgelines or deserts where a high solar capacity is present, the need for new transmission lines can be overwhelming. Second, land use issues must be considered—solar thermal power plants require significant amounts of land, and may have an appreciable environmental impact. In the U.S., the federal government has placed a moratorium on new solar projects on public land until it studies their environmental impact, which is expected to take about two years. The Bureau of Land Management has indicated that an extensive environmental study is needed to determine how large solar plants might affect the land/environment.

Finally, according to some industry observers, huge desert-bound solar power plants are sub-optimal in that transmission and other losses or inefficiencies may be experienced. Instead, solar power generation near the user's premises is particularly advantageous in terms of low transmission cost and marginal use of land.

Based the foregoing, it is clear that a need exists for an improved thermoelectric power generation system architecture and methods that can overcome the aforementioned problems associated with the various technologies. Ideally, such architecture and methods would be environmentally friendly (e.g., employ no fossil fuel), allow thermal energy to be stored and used in a controlled and safe manner so that electric power can be produced in a continuous fashion, and minimize the transmission cost, land use and utilization of gas, water or steam.

### SUMMARY OF THE INVENTION

The present invention satisfies the aforementioned need by an improved thermoelectric power generation system and method for thermoelectric power generation.

In a first aspect of the invention, a thermoelectric power generation system is disclosed. This system architecture generally comprises a solar collector that consists of a plurality of Fresnel lenses that concentrate sunlight and direct it to a receiver; the aforementioned receiver is adapted to receive concentrated sunlight which heats the phase change material contained by the receiver, a first storage device adapted to store heated phase change material from the receiver, a power conversion unit that contains, among other things, the thermopile for converting thermal power into electric power, and a second storage device adapted to store cold phase change material after the heat is consumed by the thermoelectric module.

In one exemplary embodiment, a thermoelectric power generation system is created by stacking up the chief components so that an integrated and thus compact thermoelectric power generation system is constructed. The receiver is positioned directly under the solar collector so that it receives concentrated sunlight from the Fresnel lenses. The cold phase change material from the second storage device (located at the bottom of the aforementioned staking structure) is pumped into the receiver where it is heated to a high temperature. The heated phase change material is then stored in the first storage device which is located right below the receiver. When a need arises, the heated phase change material is directed to the power conversion unit located right below the first storage device where the heated phase change material keeps a high temperature on the hot side of the thermopile while cooling fins ensure the other side cool. After the heat is consumed by the thermopile, the cold phase change material flows back to the second storage device. The cycle repeats itself to produce electricity.

In the exemplary embodiment, unlike the conventional thermoelectric power generators, thermal power generated by concentrated sunlight is advantageously used to replace the fossil fuel to create temperature difference and thus to produce electric power. Additionally, the thermoelectric power generation system based on the present invention does not engage large amount of water, steam, turbine, etc. and is therefore very quite and highly reliable. Furthermore, since the electric power is produced in a distributed manner, no major transmission lines are required. Finally, the use of phase change material makes it possible to store large amount of thermal energy and thus to provide a more predictable and dependable capacity.

In a second aspect of the invention, an apparatus for generating electrical power is disclosed. In one embodiment, the apparatus comprises a solar thermal energy collector, a heat conducting interface coupled to the solar thermal energy collector and adapted to contain a material configured to store thermal energy, the material absorbing thermal energy from the interface, and at least one thermocouple adapted to convert the solar thermal energy to electricity.

In one variant, the solar thermal energy collector comprises one or more Fresnel lenses.

In another variant, the apparatus further comprises a storage device adapted to store the material, the storage device being insulated in order to retain the absorbed heat. In a further variant, the heat conducting interface comprises a declined spiral tube adapted to utilize potential energy to direct the material to the storage device.

In yet another variant, the apparatus further comprises at least one pump, the pump adapted to propel the material to the at least one thermocouple when electricity is desired. In another variant, the material comprises molten salt.

In another variant, the apparatus further comprises a storage device adapted to retain the material which has no absorbed thermal energy therein.

In another embodiment, the apparatus comprises a mechanism for receiving radiant energy, a mechanism for storing the radiant energy as heat, and a mechanism for converting the stored heat into electrical power.

In one variant, the mechanism for receiving radiant energy comprises one or more Fresnel lenses.

In another variant, the mechanism for storing radiant energy comprises at least one material adapted to store the energy as heat. In one facet, the material comprises molten salt. In another facet, the apparatus further comprises at least one first storage device adapted to store the material at a first temperature and at least one second storage device adapted to store the material at a second temperature, the storage devices being insulated to facilitate retention of the first and second temperatures, respectively. In another facet, the material absorbs radiant energy by passing through a heat conducting interface coupled to the mechanism for receiving radiant energy and adapted to comprise a shape having one or more turns, the heat conducting interface being placed substantially on an incline so as to direct the material to the first storage device. In another facet, the apparatus further comprises a first pump adapted to propel the material at said first temperature from the first storage device to the mechanism for converting the stored heat into electrical power, and a second pump adapted to propel the material at the second temperature from the second storage device to the heat conducting interface.

In yet another variant, the mechanism for converting the stored heat into electrical power comprises at least one thermocouple.

In a third aspect of the invention, a method for collecting sunlight is disclosed. The method generally comprises forming an octagon-shaped solar collector by deploying a plurality of Fresnel lenses. The orientation of these Fresnel lenses is organized in such a manner that collectively, they maximize the amount of solar energy that is collected by the receiver for the entire day. It is clear that only the sun-facing surfaces of the octagon-shaped collector need to be covered with Fresnel lenses. The non sun-facing surfaces can be covered with low-cost materials and thus the total system cost can be reduced. It should be noted that the solar collector according the present invention not only provides the concentrated solar power needed to heat the phase change material inside the receiver, but also offers a creative design that significantly reduces the overall system footprint and cost.

In a fourth aspect of the invention, a method for receiving concentrated sunlight is disclosed. The method generally comprises receiving sunlight at a receiving device consisting of a circulation tube made from a metal or alloy with very high thermal conductivity, pumping, via a circulation pump, phase change material from a cold thermal storage device into the receiving device, heating the phase change material by the concentrated sunlight. The phase change material circulates inside the circulation tube to absorb heat. The heated phase change material is subsequently directed to the hot thermal storage device where it gets stored. It should be noted that the distance between the solar collector and the circulation tube is determined by the focal lengths of the Fresnel lenses. Finally, the size of the circulation tube and the size of the Fresnel lenses are dictated by the system capacity.

In a fifth aspect of the invention, an improved power conversion unit is disclosed. This power conversion unit generally comprises: a thermopile which consists of a plurality of thermocouples situated in a sealed section of the power conversion unit; a thermal radiator which is responsible for circulating the heated phase change material (as heat transfer fluid) so that the temperature at the hot junctions of the thermocouples is maintained at a high point (typically around several hundred ° C.); a plurality of cooling fins that allow the free movement of ambient air through them so that the cold junctions of the thermocouples can be cooled; and a fin duct which acts as a ventilation pipe, causing ambient air to flow through the cooling fins, thus cooling the thermopile.

In a sixth aspect of the invention, a method of generating electrical power is disclosed. In one embodiment, the method comprises receiving radiant energy from the sun, absorbing the radiant energy by a material adapted to store the energy by increasing from a resting temperature, and converting the stored energy to electric potential via one or more thermocouples.

In one variant, the act of receiving the radiant energy comprises concentrating the radiant energy from the sun via one or more Fresnel lenses.

In another variant, the material adapted to store the energy comprises molten salt.

In yet another variant, the act of absorbing further comprises providing an interface between the material and the solar energy. In another variant, the material having the increased temperature relative the resting temperature is stored at an insulated storage device and is non-continuously pumped to the one or more thermocouples.

### BRIEF DESCRIPTION OF THE DRAWINGS

The features, objectives, and advantages of the invention will become more apparent from the detailed description set forth below when taken in conjunction with the drawings, wherein:

FIG. 1 is a block diagram of an exemplary thermocouple according to the prior art.

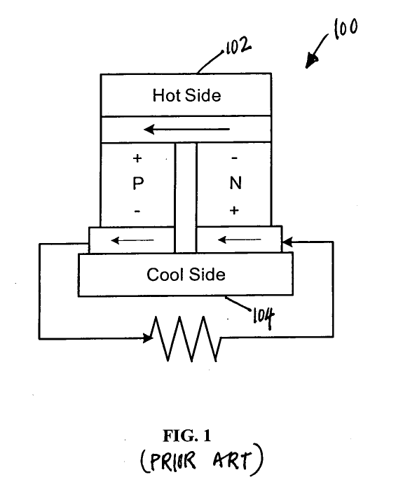

FIG. 2 is a graphical representation of a first exemplary embodiment of the electric power generation system according to the present invention.

FIG. 2a is a graphical representation of a second embodiment of the electric power generation system according to the present invention, wherein natural circulation is utilized.

FIG. 3 is a top elevation view of an exemplary solar collector for use with the exemplary electric power generation system of FIG. 2.

FIG. 4 is a top elevation view of an exemplary receiver for use with the exemplary electric power generation system of FIG. 2.

FIG. 5 is a graphical representation of an exemplary power conversion unit for use with the exemplary power generation system of FIG. 2.

FIG. 6 is a logical flow diagram illustrating one embodiment of the generalized method of generating electric power according to the present invention.

### DETAILED DESCRIPTION

Reference is now made to the drawings wherein like numerals refer to like parts throughout.

As used herein, relational terms such as first and second, top and bottom, and the like may be used solely to distinguish one entity or action from another entity or action without necessarily requiring or implying any actual such relationship or order between such entities or actions. The terms “comprises”, “comprising”, “has”, “having”, “includes”, “including”, “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus.

As used herein, the term “access point” or “AP” refers generally and without limitation to a network access point (e.g., such as a gateway or router) which allows access for one device to one or more other networks. For example, one type of access point might comprise an Ethernet router. Another type of access point might comprise an IEEE Std. 802.11 Wi-Fi™ “AP”. These terms should in no way be construed as to be limiting to a particular network standard, protocol, or topology.

As used herein, the term “application” refers generally to a unit of executable software that implements a certain functionality or theme. The themes of applications vary broadly across any number of disciplines and functions (such as on-demand content management, e-commerce transactions, brokerage transactions, home entertainment, calculator etc.), and one application may have more than one theme. The unit of executable software generally runs in a predetermined environment.

As used herein, the term “Bluetooth” refers without limitation to any device, software, interface or technique that complies with one or more of the Bluetooth technical standards, including Bluetooth Core Specification Version 1.2, Version 2.0, and Version 2.1+ EDR.

As used herein, the term “circuitry” refers to any type of device having any level of integration (including without limitation ULSI, VLSI, and LSI) and irrespective of process or base materials (including, without limitation Si, SiGe, CMOS and GaAs). ICs may include, for example, memory devices (e.g., DRAM, SRAM, DDRAM, EEPROM/Flash, and ROM), digital processors, SoC devices, FPGAs, ASICs, ADCs, DACs, transceivers, memory controllers, and other devices, as well as any combinations thereof.

As used herein, the term “computer program” or “software” is meant to include any sequence or human or machine cognizable steps which perform a function. Such program may be rendered in virtually any programming language or environment including, for example, C/C++, Fortran, COBOL, PASCAL, assembly language, markup languages (e.g., HTML, SGML, XML, VoXML), and the like, as well as object-oriented environments such as the Common Object Request Broker Architecture (CORBA), Java™ (including J2ME, Java Beans, etc.), Binary Runtime Environment (BREW), and the like.

As used herein, the term “integrated circuit (IC)” refers to any type of device having any level of integration (including without limitation ULSI, VLSI, and LSI) and irrespective of process or base materials (including, without limitation Si, SiGe, CMOS and GaAs). ICs may include, for example, memory devices (e.g., DRAM, SRAM, DDRAM, EEPROM/Flash, and ROM), digital processors, SoC devices, FPGAs, ASICs, ADCs, DACs, transceivers, memory controllers, and other devices, as well as any combinations thereof.

As used herein, the term “memory” includes any type of integrated circuit or other storage device adapted for storing digital data including, without limitation, ROM. PROM, EEPROM, DRAM, SDRAM, DDR/2 SDRAM, EDO/FPMS, RLDRAM, SRAM, “flash” memory (e.g., NAND/NOR), and PSRAM. As used herein, the terms “microprocessor” and “digital processor” are meant generally to include all types of digital processing devices including, without limitation, digital signal processors (DSPs), reduced instruction set computers (RISC), general-purpose (CISC) processors, microprocessors, gate arrays (e.g., FPGAs), PLDs, reconfigurable compute fabrics (RCFs), array processors, secure microprocessors, and application-specific integrated circuits (ASICs). Such digital processors may be contained on a single unitary IC die, or distributed across multiple components.

As used herein, the terms “network” and “bearer network” refer generally to any type of data, telecommunications or other network including, without limitation, data networks (including MANs, PANs, WANs, LANs, WLANs, micronets, piconets, internets, and intranets), hybrid fiber coax (HFC) networks, satellite networks, cellular networks, and telco networks. Such networks or portions thereof may utilize any one or more different topologies (e.g., ring, bus, star, loop, etc.), transmission media (e.g., wired/RF cable, RF wireless, millimeter wave, optical, etc.) and/or communications or networking protocols (e.g., SONET, DOCSIS, IEEE Std. 802.3, 802.11, ATM, X.25, Frame Relay, 3GPP, 3GPP2, WAP, SIP, UDP, FTP, RTP/RTCP, H.323, etc.).

As used herein, the terms “network interface” or “interface” typically refer to any signal, data, or software interface with a component, network or process including, without limitation, those of the FireWire (e.g., FW400, FW800, etc.), USB (e.g., USB2), Ethernet (e.g., 10/100, 10/100/1000 (Gigabit Ethernet), 10-Gig-E, etc.), MoCA, Serial ATA (e.g., SATA, e-SATA, SATAII), Ultra-ATA/DMA, Coaxsys (e.g., TVnet™), radio frequency tuner (e.g., in-band or OOB, cable modem, etc.), Wi-Fi™ (e.g., 802.11a,b,g,n, or any draft standards relating thereto), WiMAX (802.16), PAN (802.15), IrDA or other wireless families.

As used herein, the term “wireless” means any wireless signal, data, communication, or other interface including without limitation Wi-Fi™ (IEEE Std. 802.11), Bluetooth, 3G (3GPP, 3GPP2, UMTS), HSDPA/HSUPA, TDMA, CDMA (e.g., IS-95A, WCDMA, etc.), FHSS, DSSS, GSM, PAN (IEEE Std. 802.15), WiMAX (IEEE Std. 802.16), MWBA (IEEE Std. 802.20), narrowband/FDMA, OFDM, PCS/DCS, analog cellular, CDPD, satellite systems, millimeter wave or microwave systems, acoustic, and infrared (i.e., IrDA).

As used herein, the terms “WLAN” and “wireless LAN” refer generally to any system wherein a wireless or air interface is employed between two devices, and which provides at least local area networking capability. Wi-Fi™ systems are one exemplary instance of WLANs.

### Overview

The present invention provides inter alia methods and apparatus for providing distributed thermoelectric power generation that are particularly advantageous in terms of zero-emissions, elimination of steam and turbines (and the complexity associated therewith) in some embodiments, low transmission cost, and most importantly dependable and substantially continuous capacity.

In the exemplary embodiment, the invention leverages concentrated solar power combined with the desirable features of phase change material to provide the necessary temperature difference required by a thermopile to produce electricity with the aforementioned benefits.

The power generation system according to the present invention can support electric power generation in conditions where PV-based and other prior art systems fall short. Such capability greatly improves the system availability, and yet affords the “zero-emission” and other desirable properties of PV based systems.

### DETAILED DESCRIPTION OF EXEMPLARY EMBODIMENTS

It is noted that while the following description is cast primarily in terms of an exemplary thermoelectric power generation system, other materials, techniques and procedures may be used in conjunction with or in place of the particular techniques described herein. For example, other phase change materials, other optical or physical configurations for gathering and focusing the incident energy, and/or other electrical generation technologies may be used consistent with the principles of the invention. Accordingly, the following discussion of the approach is merely exemplary of the broader concepts.

It will also be appreciated that while described generally in the context of a consumer (i.e., home) end user domain, the present invention may be readily adapted to other types of environments including, e.g., commercial/enterprise, and government/military applications. Yet other applications are possible.

### Thermoelectric Power Generation System—

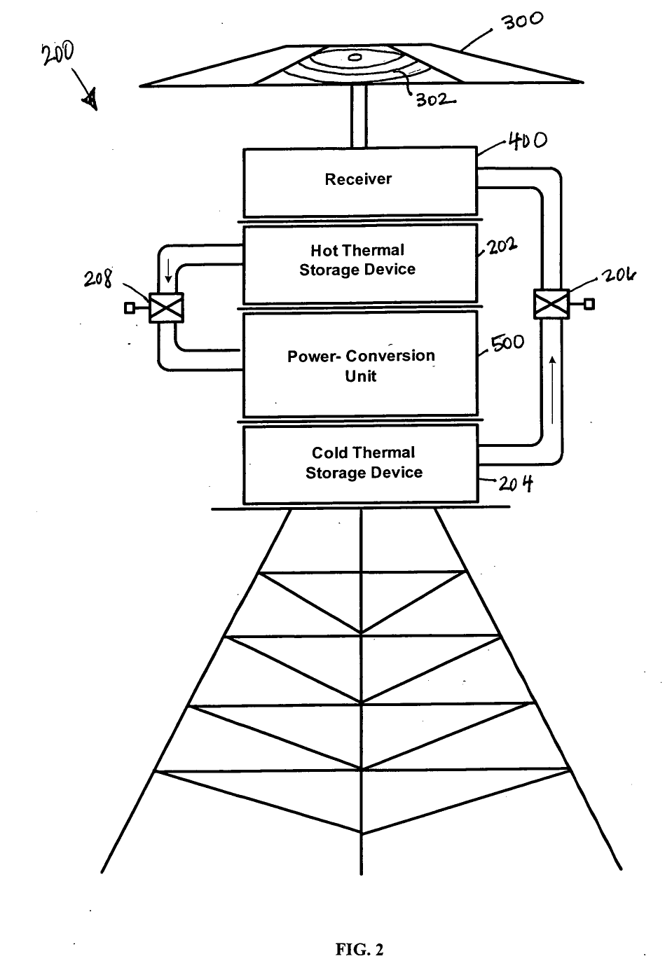

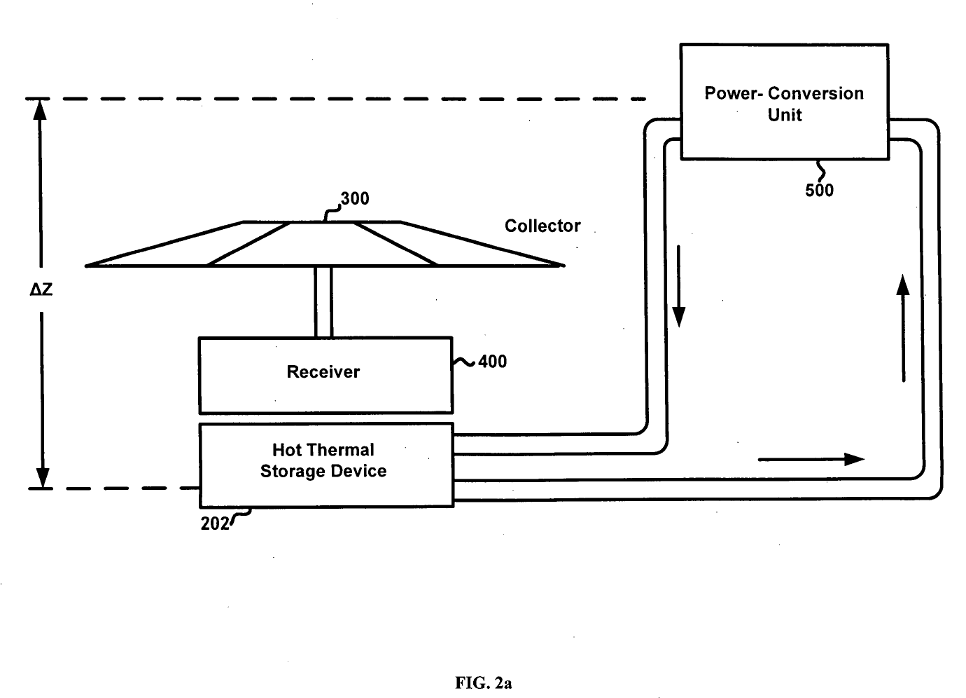

Referring now to FIG. 2, one exemplary embodiment of the power generation system 200 architecture according to the present invention is illustrated. In this embodiment, the power generation system 200 comprises a solar power collector 300; a solar power receiver 400; a hot thermal storage device 202; a power conversion unit 500; and a cold thermal storage device 204. In the illustrated embodiment, the system is created by stacking up the chief components so that an integrated and thus compact power generation system 200 is constructed. The system may further comprise pumps 206, 208, which will be discussed in greater detail below. A phase change material adapted to retain thermal energy is utilized to store the radiant energy from the sun. The phase change material is provided to the receiver 400 where it is heated. The stored energy is then converted, at the power conversion unit 500, into electrical power.

Although the illustrated embodiment depicts a particular configuration of the components with respect to one another, it is appreciated that other configurations including embodiments having one or more components not stacked, being stacked in a different order, or being mounted on other types of platforms than the “tower” shown in FIG. 2 may be utilized consistent with the present invention as well.

In one embodiment, the phase change material described above comprises molten salt (e.g., 60%/40% sodium-nitrate and potassium-nitrate, respectively), although other materials may be used as well. The heated molten salt (i.e., heated by radiant energy from the sun) is stored at the “hot” thermal storage device 202. In one embodiment, the storage device 202 is insulated using any number of well-known insulation materials/techniques such as using a non-flammable or high-temperature fibrous or other insulating material, use of an air or gas insulating gap, etc., to maintain the molten salt at approximately 1000° F. After the thermal energy of the heated molten salt is converted to electrical power (described below), the molten salt achieves a second temperature, lower than the heated temperature. The cooled molten salt may be stored at the “cold” thermal storage device 204 (“cold” here being a relative term as well). In one embodiment, the temperature of the molten salt inside the cold thermal storage device 204 is maintained at approximately 550° F.; the molten salt will remain in the liquid phase at both the “hot” and “cold” temperatures.

It will be appreciated that, in an instance where the temperature of the molten salt inside the cold thermal storage device 204 drops below the melting point, a heater (not shown) may be needed to heat the molten salt so that it can stay in the liquid phase in order to be pumped into the receiver. Such a heater may be for example a resistive element or other electrically powered device (the electrical power for which can be tapped off of the output of the apparatus 200), a gas (e.g., propane or butane) heater, a convective (hot air) heater, or other such mechanism of the type well known to those of ordinary skill. However, it is noted that as long as the cold thermal storage device 204 has an appreciable level of thermal insulation, such heating will not be required.

It should also be noted that molten salt is not the only material that can be used for the operation of the electric power generation system disclosed here; other alternative materials may be utilized as well. For example, the system 200 may utilize ionic liquids, room-temperature ionic liquids, deep eutectic solvents (DES) and the like which can be selected to provide the desired heat-retaining and solid/liquid phase properties.

In the illustrated embodiment of FIG. 2, the solar collector 300 (discussed in greater detail below) concentrates sunlight (i.e., radiant visible and other wavelength electromagnetic energy from the sun) into the receiver 400, which is positioned directly under it. In one embodiment, sunlight is concentrated by utilization of one or more focusing lenses 302 (such as Fresnel lenses) on the collector 300. “Cold” phase change material from the second storage device 204 (located at the bottom of the aforementioned stacked structure) is pumped into the receiver 400 via the first pump 206, where it is heated to a higher temperature by the radiant energy from the sun concentrated into the receiver 400. The heated phase change material is then stored in the first storage device 202 which in the illustrated embodiment is located right below the receiver 400.

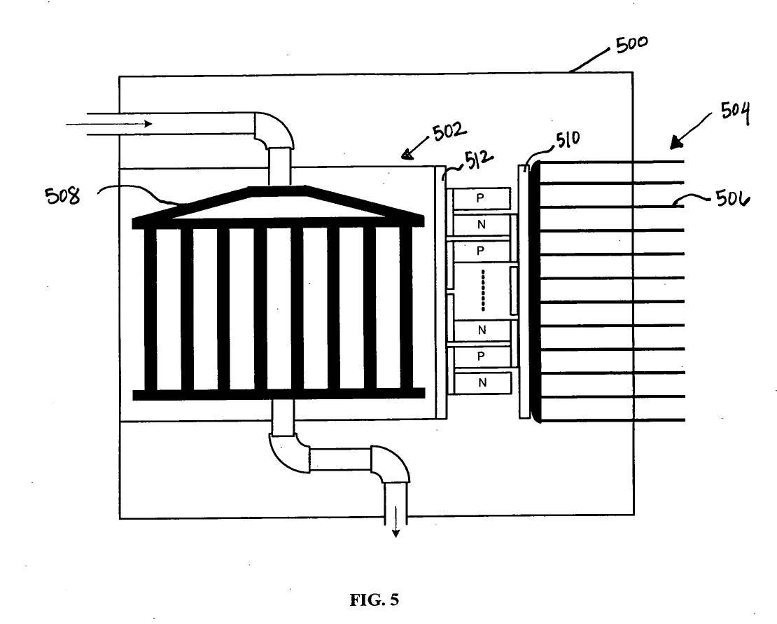

When a need arises, the heated phase change material is pumped into the power conversion unit 500 located right below the first storage device 202 via the second pump 208. At the power conversion unit 500 (see FIG. 5), the heated phase change material keeps a high temperature on the hot side 502 of the thermopile, while cooling fins 506 ensure the “cold” side 504 remains comparatively cool. After the heat is consumed by the thermopile, the cold phase change material flows back to the second storage device 204. The cycle repeats itself to continuously (if desired) produce electricity.

As illustrated in FIG. 2, the system 200 employs two pumps 206, 208 to keep the phase change material moving through the various parts of the electric power generation system 200; a first pump 206 to push material having a lower temperature to the receiver 400 from a storage device 204 separated therefrom, and a second pump 208 to push heated material from a storage device 202 for storing material having a higher temperature to a device for converting the stored thermal energy into electrical power 500. In the illustrated embodiment, the pumps 206, 208 consume a much smaller amount of electric power than is generated by the system 200.

In addition, these pumps 206, 208 operate in a non-continuous manner. In other words, the pumps 206, 208 are adapted to only operate when necessary. Thus, when the system is not in use or when electrical power is not required the pumps 206, 208 cease pushing the material within the system 200.

Furthermore, the electric power generation system 200 may be utilized to provide itself with the power needed to operate the pumps 206, 208. For example, during the daytime, both pumps 206, 208 can operate by drawing electric power from the system 200. It is noted that during the night-time, there is no need to utilize power from the system 200 to operate the pump which provides phase change material to the receiver 400 (pump 206) because there is not sufficient radiant energy to increase the temperature of the material. Thus, only the pump which provides stored heated material to the power conversion unit 500 will require electric power from the system 200 in order to cause the phase change material stored in the hot thermal storage device 202 to produce electricity at night-time.

It will also be appreciated that other mechanisms or techniques can be used to circulate the liquid-phase material within the apparatus 200. For example, well-understood “natural circulation” techniques may be used, wherein differential temperature (and hence density) fluid is circulated through a loop including a heat source and heat sink by virtue of this differential. One such everyday example of a natural circulation loop is the General Electric S8G submarine nuclear reactor plant, wherein the reactor core (heat source) is disposed at an elevation less that that of the heat sink (steam generators), and no pumps are used to circulate reactor coolant. The water heated by the reactor core rises (due to lower density) to the steam generator(s), where the heat is drawn off to a secondary loop, and the resulting cooled liquid of comparatively higher density falls back to the lower-elevation reactor core to be reheated again. Such a geometry and technique can readily be applied to the present invention, such as for example by raising the power conversion device 500 (heat “sink”) to an elevation above the heat source (receiver/thermal storage device), which receives heat from the Fresnel lens or other such mechanism, thereby inducing a natural circulation of the molten salt within the “loop”. See FIG. 2a for one such alternate embodiment. Other such alternatives will be readily appreciated by those of ordinary skill in the relevant art.

As noted above, despite their widespread use, PV panel technologies suffer the limitation of most renewable technologies: an unpredictable availability due to weather variations, not to mention that they can not operate at all during nighttime (darkness). One salient advantage of the electric power generation system according to the present invention, compared to traditional PV panels, is that the present system 200 can produce electricity 24 hours a day and 7 days a week; the ability to produce electricity depends primarily on the size of the hot thermal storage device 202 and the amount of heated phase change material the storage device 202 can hold (and the temperature to which it is heated). In other words, according to the present invention, electricity may be provided during the night and in times of inclement weather. Accordingly, one exemplary embodiment of the invention utilizes hot and cold storage devices (and associated piping loops) that are sized to accommodate enough molten salt to provide uninterrupted energy production for a design basis period of time (e.g., 3 days of no solar radiation). The sizing may be adjusted according to other factors as well (which can contribute to the design basis), including e.g., (i) the energy demands of the user; (ii) the latitude of the user (related to the number of hours of daylight per given calendar day, and the intensity of the solar radiation at any given time of day); (iii) the average ambient temperature of the user's location (colder ambient temperatures will cause greater heat loss or rejection, thereby lowering efficiency), and so forth.

### Solar Collector Apparatus—

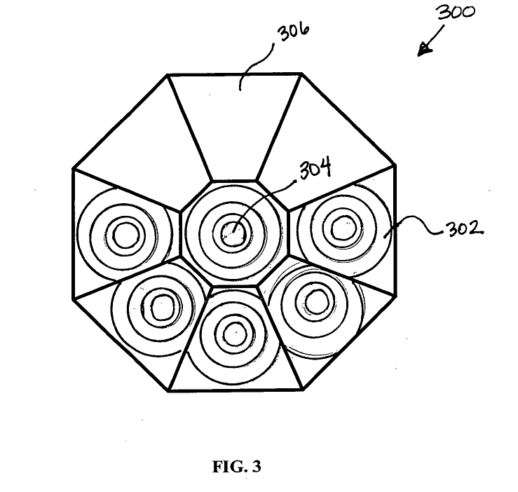

FIG. 3 illustrates an exemplary embodiment of the solar collector 300 according to the present invention. In this embodiment, the collector 300 forms an octagon-shaped rooftop for the system 200. Alternative shapes may also be utilized including, for example, circles, triangles, squares, rectangles, hexagons, heptagons, etc. According to the embodiment of FIG. 3, the octagon-shaped rooftop is comprised of one or more panels having a plurality of lenses 302, and may also optionally comprise one or more non-optical panels 306. Only those panels facing the sun need to be covered with focusing lenses 302. The non sun-facing panels may be covered with low-cost materials, thus reducing the total system cost.

Moreover, it will be appreciated that secondary lenses or arrays may be used, so as to e.g., capture light energy which is diffused or reflected by the lenses or other structures/components. As is well known, even the most absorptive or transmissive surfaces will reflect or reject a portion of the light energy incident thereon (due to, e.g., the interface of different media having different refractive indexes, etc.). This reflected or lost energy can be recaptured by secondary lenses or other energy collectors, reflectors to as to make at least some use of it, and ideally enhance the efficiency of the device.

The abovementioned techniques and methods may further incorporate anti-reflective (AR) coating techniques. AR coating involves the application of an optical coating to the surface of a lens to reduce reflection. Utilization of AR coating in the present invention improves the efficiency of the system by reducing the amount of light that is “lost” to reflection. In one embodiment, the lenses 302 of the present invention may be coated with transparent thin film structures with alternating layers of contrasting refractive index. The thickness of each layer is chosen to produce destructive interference of the reflected beams, and constructive interference of the transmitted beams.

Collectively, the lenses 302 concentrate the sunlight on the receiver 400 (located just below the center of the collector 300) in such a manner that the phase change material circulating inside the receiver 400 is heated evenly and rapidly. In one embodiment, this is achieved by utilizing Fresnel lenses 302 of the type well known in the optical arts and having corresponding focal points 304. As is well known in the optical arts, Fresnel lenses 302 do not reflect sunlight, but rather pass the sunlight. In the exemplary embodiment of FIG. 3, the focal points 304 of the Fresnel lenses 302 are organized so that the sunlight is focused over the desired receiving area of the receiver 400.

The size of the light beam concentrated on to the receiver 400 can be increased by moving the lens 302 relative to the lens focal point 304. Such movement also helps to evenly distribute the heat. Such movement may be accomplished for example by moving the entire array 300, moving individual lenses or panels thereof, etc. In order to maximize the sunlight collected by the lenses 302, the orientation of these lenses 302 must be carefully calculated and designed.

The non-optical panels 306 may be optionally used to serve only decorative and/or support or structural purposes, and do not contribute to the heating of the phase change material. Generally, these may be used to complete the overall shape of the collector 300, thereby providing stability to the geometry of the collector 300 and give an aesthetically pleasing symmetric shape. As noted, the use of non-optical panels 306 is optional; other embodiments may be comprised completely of one or more lenses 302, including Fresnel lenses as illustrated in FIG. 3. Moreover, the non-optical panels can be folded down out of the way (or completely removed or obviated in the design altogether), so as to allow incident solar radiation to impinge directly on the receiver (i.e., avoid blocking light from hitting the receiver top).

Positioning of the collector 300 is accomplished by ideally placing the sunlight focusing Fresnel lenses 302 in a position to receive direct sunlight for a substantial portion of the day. Positioning will depend on the geography of the premises where the system 200 is employed as well as other factors well known in the PV system installation arts (including for example the elevation of the apparatus 200, latitude, time of year, etc.). A mechanical and/or computerized tracking mechanism (not shown) may also be optionally utilized to track the movement of the sun and re-position the collector 300 in response thereto. Utilization of a tracking mechanism, as described, may permit a user to decrease the total number of lenses 302, such as from six to four in the illustrated embodiment, or alternatively obtain greater duty cycle (i.e., more incident energy “captured” during the course of a given day with the same number of lenses 302). One of the significant advantages of utilizing a tracking mechanism is that it provides an optimized orientation of the collector 300 throughout the day, thereby maximizing efficiency. However, it is generally understood that adding moving parts to a power generation system may cause reliability and/or maintenance issues. In addition, a tracking mechanism may require electric power to operate, which is less desirable. In one embodiment, the electric power required to operate the tracking mechanism may be supplied from the system 200 itself, although other sources may be used.

In one embodiment, the tracking system comprises a controller (e.g., microcontroller or digital processor) and associated memory, etc. adapted to control one or more servo drive motors, which through gear reduction or similar approaches, move various components (e.g., collector 300) of the system 200 to desired positions. The controller may include for example a computer program adapted to estimate the sun's position in the sky for a given date/time, and determine an appropriate correction (given the known location of the apparatus 200, its orientation, etc.). Alternatively, a sensor (e.g., IR or photo-electric) can be used to provide actual sensed input to the controller as to the location of the sun in order to adjust orientation or position, somewhat akin to a seeker head on an IR-guided munition.

It is appreciated that in larger-scale power generation systems, a tracking mechanism may be employed without significant effect on the amount of electric power produced. This is primarily because such larger-scale power generation systems utilize a considerably larger number of lenses 302. As the system capacity increases, the amount of electric power drawn by the tracking device becomes relatively less significant.

Additionally, the collector 300 may employ mechanisms such as hinges, swivels, friction clamps, etc., whereby a user may manually adjust the position of the collector 300 without the use of a mechanical tracking mechanism, much as one adjusts a patio table umbrella over time as the sun “moves”. Enabling user manual adjustment of the collector 300 will not draw electric power from the system, although it does require periodic user intervention.

It is further appreciated, as discussed above, that the panels (including the panels comprising Fresnel lenses 302) may be individually adjusted via the mechanical tracking mechanism and/or manual methods discussed above, so as to better focus the radiant energy onto the receiver 400. Moreover, individual lenses (or arrays of lenses, such as within a given panel) can be articulated and adjusted so as to maintain optimized focus and/or direction.

It will also be appreciated that the exterior of the apparatus 200 can be constructed and colored/textured in such a fashion as to maximize the absorption of incident solar energy that is otherwise not captured by the lens. As is well known, black surfaces absorb appreciably more solar energy and have higher temperatures than light or white surfaces, and those of a somewhat rougher texture often absorb more heat than those which are “mirror polished” or very smooth. Hence, the exterior of the collectors, receivers, etc. can be optionally painted or colored black, and/or textured (e.g., “wrinkle-finished” or the like) to enhance energy absorption. This must be balanced, however, with the enhanced radiation capabilities of such “black bodies”; i.e., an object that is significantly hotter than its surroundings will radiate more heat if painted black than white). Highly reflective coatings (e.g., mirror or light-color polished finishes, or even aluminized finishes such as aluminum foil/coating) can also be applied to the interior of components on the device 200 proximate to the hot and cold storage devices and other heat-carrying components, thereby reflecting infrared radiation (longer wavelength electromagnetic radiation) that may be generated from such hot components), thereby increasing system efficiency.

It will further be appreciated that while a single array of collector devices 300 is shown, multiple such collector (e.g., Fresnel) arrays can be used to capture light energy arriving from multiple different paths at the same time or alternatively at different times (such as during different times of the day as the user location moves relative to the sun).

In another embodiment, the collector panel(s) and lenses 302 can be fitted within a fixed structure, such as embedded in the roof of a house or out-structure (e.g., garage or barn). While such an installation is not adjustable per se, it does afford the ability to embed a large number of lenses which can be individually tuned to focus on a particular spot (i.e., “phased array” concept), thereby compensating for lack of movement. Such an installation would be particularly useful in open locations (e.g., desert) within predominantly sunny clients, since portions of the structure will be exposed to incident solar radiation for large portions of the day (thereby rendering the precise focusing of a movable array less important).

### Solar Receiver—

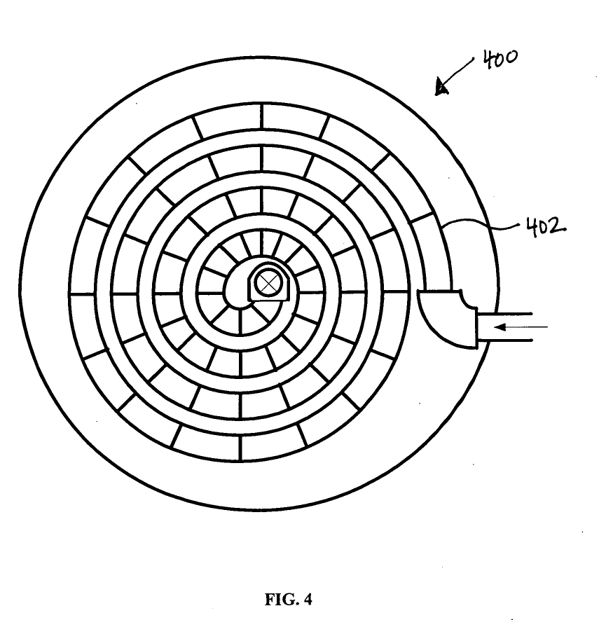

Referring now to FIG. 4, an exemplary solar receiver 400 according to the present invention is illustrated. As shown, the solar receiver 400 generally comprises a circulation tube 402 made from a metal or alloy (e.g., copper, copper/nickel, etc.) with very high thermal conductivity. The position of the circulation tube 402 is determined by the focal lengths of the lenses 302 utilized in the device 200. In the instance where Fresnel lenses 302 are utilized, the focal length will be shorter thus enabling a more compact system 200. In the illustrated embodiment, the circulation tube 402 is designed such that it forms a spiral-like shape. The sunlight, concentrated by the Fresnel lenses 302, heats the phase change material within the tube 402 throughout the length of the spiral. As the phase change material flows through the tube, it not only gets closer to the center of the device, but also flows downwards. The small incline is intended to allow the phase change material to flow downwards without a pump due to the forces of gravity. If one looks at the device from the side (not shown), the device resembles a funnel with its narrow stem connected to the hot thermal storage device 202.

Alternative embodiments may utilize other, non-spiraled (e.g., non-funnel) shapes and/or may comprise a relatively planar or non-inclined surface. In the instance that the circulation tube 402 does not comprise a funnel shape, an additional pump (not shown) may be required to push the heated material to a storage device.

Moreover, multi-tube arrays or shapes can be utilized, so as to avoid any gaps in the tube surface area (which minimizes losses and increases efficiency). For instance, in one such variant, a planar array of tubes is used. Vertically stacked tube arrays may also be used.

Further, alternative embodiments may be configured so as to feed directly to the conversion device 500. The direct delivery may be accomplished via a pump from the receiver 400 or, as described above, a funnel-shaped tube 402 within the receiver 400 or natural circulation (FIG. 2a). The conversion device 500 of such an embodiment would be adapted to immediately convert the thermal energy of the phase change material to electrical potential. The conversion device 500 is then further adapted to store the electrical potential at a storage device (not shown).

Phase change material from the cold thermal storage device 204 is pumped into the circulation tube 402 by the pump 206. In the circulation tube 402, the phase change material circulates and absorbs heat generated by concentrated sunlight. The heated phase change material is subsequently directed to the hot thermal storage device 202 where it is stored. It should be noted that use of a circulation tube 402 helps the phase change material to absorb maximum amount of heat in an evenly manner throughout the tube 402 and thus helps to increase the overall system efficiency significantly, although other shapes and configurations of heat exchange mechanism may be used. For instance, the invention could conceivably be practiced using direct impingement of short-focal length Fresnel lenses on the surface of the molten salt material itself, such as where the latter material is contained in a reservoir with a top having one or more Fresnel lenses mounted therein. Since the molten salt need not be contained with in a pressurized system, such “open” architectures are feasible as well. These approaches have the advantage of allowing for direct impingement of the concentrated solar energy on the medium itself, versus having the heat transferred through an interposed structure (e.g., tube).

Another advantage of utilizing a circulation tube 402 such as that of FIG. 4 is that it significantly reduces the overall system footprint. In many solar thermal systems, extremely large arrays of mirrors, focusing the rays of the sun onto miles and miles of pipes, help to heat water to run massive steam turbines. While these systems certainly have their merits and will find their usefulness in certain circumstances, the electric power generation system 200 according to the present invention offer an extremely attractive alternative due to its agile or portable architecture, ability to operate in unfavorable or inconsistent whether conditions, elimination of steam and turbine(s), and low transmission cost/losses.

It will also be appreciated that tube diameter and/or wall thickness may affect the efficiency of the receiver 400. Specifically, as the tube diameter increases, the surface area changes according to well-known mathematical laws (L×2pr, assuming a cylinder), and the heat rejection/conduction is related to the surface area (and the differential temperature). Moreover, the conduction of heat through the tube wall may be affected by the thickness of the wall. Hence, one may readily adjust these parameters during design in order to optimize heat transfer efficiency or other parameters of interest (e.g., latency or duty cycle). For instance, thinner-walled (e.g., 1/16 in.), larger diameter tubes may be found to provide better heat-up rate, but may also reduce duty cycle due to e.g., radiant heat losses from the tube(s). Mechanical rigidity and robustness must also be considered for the particular design contemplated.

### Power Conversion Unit—

FIG. 5 illustrates an exemplary power conversion unit 500 according to one embodiment of the present invention. The power conversion unit 500 circulates the heated phase change material (as heat transfer fluid) through a thermal radiator 508. The thermal radiator 508 is disposed near the section 502 of the power conversion unit 500 where one or more thermopiles is/are located. When hot phase change material flows through the thermal radiator 508, the hot junctions 512 of the thermocouples are heated to a high temperature (in a similar fashion to a gas burner burning inside a combustion chamber next to the thermopile, as in many prior art systems). Thermopiles are well known in the art as electronic devices which convert thermal energy into electrical energy. A thermopile is generally comprised of thermocouples connected usually in series or less commonly in parallel. Thermocouples convert thermal potential difference into electric potential difference. Exemplary thermopiles useful with the present invention include inter alia, Hi-Z models HZ-2, HZ-9, HZ-14, and HZ-20 sold by Hi-Z Technology, Inc. of San Diego, Calif., as well as the various thermopiles and/or thermocouples sold by other retailers such as, for example, Nanmac Corporation in Farmingham, Mass., Omega Engineering, Inc. of Stamford, Conn., and Measurement Computing Corporation in Norton Massachusetts.

The cooling of the “cold” side 504 of the thermopile is accomplished by the free ambient air flow through the cooling fins 506 which transfer the heat to the surrounding air. Such air flow may be naturally induced (e.g., via wind, convective currents, etc.), and/or may be forced, such as via an air cooling fan or the like. Cryogenic cooling (e.g., liquid nitrogen or the like) may also be used if desired, although this approach adds complexity and cost.

The temperature difference between the hot side 502 and cold side 504 of the thermopile is in the illustrated embodiment maintained by establishing a steady flow of heat transfer fluid through the thermal radiator 508. In natural circulation variants (e.g., FIG. 2a), the cooling fins 506 or other such mechanisms can be used to reject sufficient heat from the “hot” side 502 of the device so as to cause the temperature of the molten fluid coming into the thermal radiator 508 to be significantly higher than that exiting the radiator 508, thereby further inducing a differential density and aiding in natural circulation.

In the embodiment of FIG. 5, as the temperature of the heat transfer fluid decreases, the fluid is pushed (either by a pump or by using gravity) out of the power conversion unit 500. In one embodiment (not shown), the fluid is pushed directly to the receiver 400. Alternatively, the fluid may be stored in a cold thermal storage device 204. The fluid may then be recycled; i.e., pulled from the cold storage 204 to the receiver 400 as the cycle repeats itself. As the cooled fluid is removed, fresh heat transfer fluid having the increased temperature discussed above is supplied to the thermal radiator 508 and another cycle gets started.

It should be noted that electrical insulation (not shown) between the hot junctions 512 and the thermal radiator 508 can be provided by an electrical insulation material. Similarly, the electrical insulation between the cold junctions 510 and the cooling fins 506 can be provided by a similar electrical insulation material. Thermal (versus electrical) insulation material is used in the surrounding areas of the hot junctions 512 so as to maintain the desired hot temperature.

In one embodiment, an inverter of the type well known in the electrical arts may be utilized. The inverter may be physically separate from the power conversion unit 500, or alternatively, may be co-located therein. An inverter is a device that takes the DC output power of DC power generation system, and converts it into (e.g., grid-compliant) AC power. Inverters are well known and thus will not be discussed in further detail herein. Other electrical components such as current/voltage regulators, transformers, filters, signal conditioners, rectifiers, and the like may be applied to the output current in order to produce the desired electrical characteristics. These components may comprise discrete (i.e., board-level) components, integrated circuits (ICs), or any other types of device or circuitry. The output of the individual thermocouples (where multiple ones are used) may also be arranged in series (voltage additive), parallel (current additive), or any other combinations thereof in order to produce the desired electrical output characteristics.

Moreover, the control system of the device 200 may be placed in wired or wireless communication with one or more external devices, such as a home user's PC that includes a computer program or application adapted to provide a user interface enabling remote control of the device (e.g., power on/off, pumps on/off, change position or steer the collector 300 manually, determine power produced, adjust output voltage, reprogramming, updating location information, resetting time/date, etc.). In that the electrical power generated by the device 200 may be “sold back” to the supplying grid (i.e., excess production not used or stored on the premises is sent to the grid), the aforementioned controller may also include a logging or similar function to help track such reverse flow and related parameters.

Device troubleshooting and maintenance sub-functions may also be included within the controller program and logic, so as to remind the user of periodic maintenance, allow failures to be diagnosed rapidly, provide interlocks and safety functions to prevent the user from exposing themselves to the superheated molten fluid medium, etc.

In one variant, the wireless interface comprises a PAN or LAN interface (e.g., Bluetooth, WiFi, etc.) or IrDA, and the user can network the device such as via a local access point so as to e.g., control it via the Internet from their office or mobile computer (e.g., laptop) or other remote location. Alternatively, an Ethernet, USB, IEEE-1394, or other similar wired connection can be utilized to provide data communication between the remote control station and the on-board controller of the system 200. It will also be appreciated that an electrical storage device may be used in conjunction with the present invention; e.g., to store electrical output of the system in a battery or similar storage cell for later use. Such an approach relieves the system 200 from at least some of its thermal storage requirements (i.e., storage of energy in the form of heat within the molten medium). This allows the thermal portions of the device 200 to be smaller than otherwise, and may extend the duty cycle of the overall device (i.e., energy stored in a battery may last longer, all else being equal, than the equivalent thermal storage. It also allows for rapid discharge situations (e.g., high current draws, such as starting a large induction motor, appliance, etc.), whereas the electrical generation by the thermoelectric system alone may not have sufficient output for such surges or situations.

### Exemplary Methods—

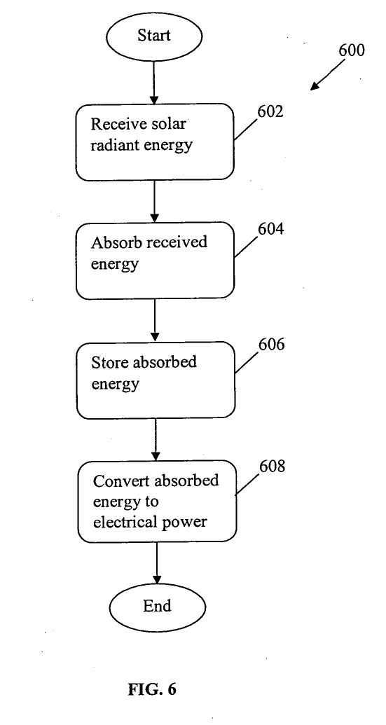

Referring now to FIG. 6, an exemplary method 600 of generating thermoelectric power is given. Per step 602 of the method, solar radiant energy is received. At step 604, the solar radiant energy is focused using the collector, and absorbed by the thermoelectric power generation system 200. In one embodiment, the radiant energy is absorbed by a heat absorbing phase change material such as the molten salt previously described herein. As discussed above, the temperature of the phase change material increases as radiant energy is absorbed. In one exemplary embodiment, the phase change material is guided through a circulation tube 402 (FIG. 4), and light rays from the sun are concentrated onto the tube 402 via the Fresnel lenses 302.

Next, at step 606, the absorbed energy is stored. In one embodiment, the energy is stored as thermal energy in the phase change material. Dissipation of the thermal energy may be minimized by insulation. The phase change material may be optionally stored in one or more thermally insulated storage devices (e.g., tanks, cylinders, chambers, etc.) until conversion thereof is required.

At step 608, the absorbed energy is converted to electrical power. In one embodiment, this is accomplished by utilization of one or more thermocouples (as discussed above). However, other mechanisms for converting thermal energy to electrical power may also be utilized consistent with the present invention. For instance, while not as desirable, a secondary loop containing water, a steam turbine, and a condenser (with pump if necessary) can be used to convert the thermal energy to electrical energy. Such steam generation technology is well known to those of ordinary skill, and accordingly is not described further herein.

Moreover, the heat energy collected in the molten medium need not be converted to electrical power if not required. For instance, a heat exchanger could be used (akin to the steam system described above) to circulate heated water (or steam) through pipes or other structures in the user's residence, such as for heating in winter (e.g., by blowing air driven by one or more fans over the heated water pipes), or for heating of the premises water heaters or pool/spa. Myriad other uses and applications will be recognized by those of ordinary skill given the present disclosure.

Once the absorbed energy has been utilized from the phase change material, the material will cool to its resting temperature and is optionally stored, at an insulated storage device, for later use in absorbing solar radiant energy.

In the foregoing specification, specific embodiments have been described. However, one of ordinary skill in the art appreciates that various modifications and changes can be made without departing from the scope of the invention as set forth in the claims below. Accordingly, the specifications and figures are to be regarded in an illustrative rather than a restrictive sense, and all such modifications are intended to be included within the scope of present invention.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pending period of this application and all equivalents of those claims as issued.

It will be recognized that while certain aspects of the invention are described in terms of a specific sequence of steps of a method, these descriptions are only illustrative of the broader methods of the invention, and may be modified as required by the particular application. Certain steps may be rendered unnecessary or optional under certain circumstances. Additionally, certain steps or functionality may be added to the disclosed embodiments, or the order of performance of two or more steps permuted. All such variations are considered to be encompassed within the invention disclosed and claimed herein.

While the above detailed description has shown, described, and pointed out novel features of the invention as applied to various embodiments, it will be understood that various omissions, substitutions, and changes in the form and details of the device or process illustrated may be made by those skilled in the art without departing from the invention. This description is in no way meant to be limiting, but rather should be taken as illustrative of the general principles of the invention. The scope of the invention should be determined with reference to the claims.

What is claimed is:

1. An apparatus for generating electrical power, said apparatus comprising:
a solar energy collector;
a heat conducting interface coupled to said solar energy collector and adapted contain a material configured to store thermal energy, said material absorbing thermal energy from said interface; and
at least one conversion device adapted to convert said thermal energy to electricity.

2. The apparatus of claim 1, wherein said solar energy collector comprises one or more Fresnel lenses.

3. The apparatus of claim 1, further comprising a storage device, said storage device adapted to store said material, said storage device being insulated in order to retain said absorbed heat.

4. The apparatus of claim 3, wherein said heat conducting interface comprises a declined substantially spiral tube adapted to utilize potential energy to direct said material to said storage device.

5. The apparatus of claim 1, further comprising at least one pump, said pump adapted to propel said material to said at least one thermocouple when electricity is desired.

6. The apparatus of claim 1, wherein said material comprises molten salt.

7. The apparatus of claim 1, further comprising a storage device adapted to retain said material which has no absorbed thermal energy therein.

8. The apparatus of claim 1, wherein said at least one conversion device comprises at least one thermocouple.

9. An apparatus for converting solar radiant energy to electrical power, said apparatus comprising:
a mechanism for receiving and directing said radiant energy;
a mechanism for storing said directed radiant energy as heat; and
a mechanism for converting said stored heat into electrical power.

10. The apparatus of claim 9, wherein said mechanism for receiving radiant energy comprises one or more Fresnel lenses.

11. The apparatus of claim 9, wherein said mechanism for storing radiant energy comprises at least one material adapted to store said energy as heat.

12. The apparatus of claim 11, wherein said material comprises molten salt comprised of sodium-nitrate and potassium-nitrate.

13. The apparatus of claim 11, further comprising at least one first storage device adapted to store said material at a first temperature and at least one second storage device adapted to store said material at a second temperature, said first and second storage devices being insulated to facilitate maintenance of said first and second temperatures, respectively.

14. The apparatus of claim 13, wherein said material absorbs radiant energy by passing through a heat conducting interface, said interface being coupled to said mechanism for receiving radiant energy and comprising a shape having one or more turns, said heat conducting interface comprising an incline so as to direct said material to said first storage device under at least force of gravity.

15. The apparatus of claim 14, further comprising:
a first pump adapted to propel said material at said first temperature from said first storage device to said mechanism for converting said stored heat into electrical power; and
a second pump adapted to propel said material at said second temperature from said second storage device to said heat conducting interface.

16. The apparatus of claim 9, wherein said mechanism for converting said stored heat into electrical power comprises at least one thermocouple.

17. A method of generating electrical power, said method comprising:
receiving radiant energy from the sun;
focusing said radiant energy to increase its spatial intensity;
absorbing said radiant energy at least partly within a material adapted to store said focused energy through increase in its temperature from a resting temperature; and
converting said stored energy to electric potential via one or more thermocouples.

18. The method of claim 17, wherein said act of receiving said radiant energy comprises concentrating said radiant energy from the sun via one or more Fresnel lenses.

19. The method of claim 17, wherein said material adapted to store said energy comprises a molten salt adapted to remain liquid at temperatures significantly above room temperature.

20. The method of claim 17, wherein said act of absorbing further comprises providing an interface between said material and said solar energy.

21. The method of claim 17, wherein said material having said increased temperature relative said resting temperature is stored at an insulated storage device and is non-continuously pumped at least proximate to said one or more thermocouples.

22. The method of claim 17, wherein said converting of said stored energy to electric potential can proceed irrespective of said receiving of radiant energy.
